(19) United States
(12) Patent Application Publication
(10) Pub. No.: US 2003/0020373 A1
(43) Pub. Date: Jan. 30, 2003

(54) Surface acoustic wave device

(76) Inventor: Masao Irikura, Kamakura-shi (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/244,625

(22) Filed: Sep. 17, 2002

Related U.S. Application Data
(63) Continuation of application No. PCT/JP01/10330, filed on Nov. 27, 2001.

(30) Foreign Application Priority Data
Jan. 17, 2001 (JP) 2001-009230

(51) Int. Cl. H03H 9/25

(52) U.S. Cl. 310/348

(57) ABSTRACT

A surface acoustic wave device is obtained at low cost in a small size while good airtightness of a vacant portion is maintained. For this purpose, the surface of a surface acoustic wave element, on which an inter digital transducer is formed, is connected to a flat-plate substrate by means of a bump with a vacant portion formed between them. In this structure, a stepped portion having a step is formed on the surface of the substrate at the edge. When the surface of the stepped portion and the outer surface of the surface acoustic wave element are covered together with a hardening resin, the hardening resin coincides with the stepped portion to attain the airtightness of the vacant portion.

### CROSS-REFERENCE TO RELATED APPLICATIONS

This is a Continuation Application of PCT Application No. PCT/JP01/10330, filed Nov. 27, 2001, which was not published under PCT Article 21(2) in English.

This application is based upon and claims the benefit of priority from the prior Japanese Patent Application No. 2001-009230, filed Jan. 17, 2001, the entire contents of which are incorporated herein by reference.

### BACKGROUND OF THE INVENTION

1. Field of the Invention

The present invention relates to a surface acoustic wave device to be used as a part of resonators resonator-form filters, and oscillators used in small mobile communication machines, and more particularly, to a surface acoustic wave device improved in sealing structure.

2. Description of the Related Art

A surface acoustic wave device (also referred to as a “SAW filter”), which is to be used as a part of resonators, resonator-form filters, and oscillators, has comb-like electrodes formed on a piezoelectric substrate. Since the surface acoustic wave device is small and light, it is suitable for use in mobile communication machines such as cellular phones.

In this field, the weight of the surface acoustic wave device is limited depending upon the electronic device to be applied. Therefore, it has been demanded to not only improve the performance but also reduce the size and cost.

The techniques contributing to cost reduction have been described in Domestic-republication of PCT International Patent Publication No. 97/02596 and Jpn. Pat. Appln. KOKAI Nos. 10-22763 and 10-64511.

In the methods proposed in these documents, a surface acoustic wave element is bonded facedown onto a flat-plate substrate and fixed and covered with a resin. In this technique, to prevent the resin from going into the vacant portion between a functioning portion (an inter digital transducer portion) of the surface acoustic wave element and the flat-plate substrate on which the surface acoustic wave element is to be fixed, the junction between the flat-plate substrate and the resin is provided outside the outer periphery of the surface acoustic wave element, thereby ensuring a relative larger area.

FIGS. 11 and 12 show sectional structures of conventional surface acoustic wave devices.

Reference numeral 30 denotes a flat surface substrate. A wiring pattern is formed on the upper surface of the flat-plate substrate 30 and connected to the underlying lead pattern etc., via a through-hole 31. A surface acoustic element 40 is arranged above the upper surface of the flat-plate substrate 30 in parallel to the upper surface. The surface acoustic device element 40 has a functioning portion (inter digital transducer portion) 41, which is formed on a piezoelectric substrate. The functioning portion 41 is arranged so as to face the upper surface of the flat-plate substrate 30.

A vacant portion 50 is provided between the opposed surfaces of the surface acoustic element 40 and the flat-plate substrate 30. This is because the surface acoustic wave element 40 has a functional property of transmitting a surface acoustic wave and therefore the opposed surfaces cannot be in contact with each other. Therefore, the bonding pads of the opposed surfaces of the surface acoustic wave element 40 and the flat-plate substrate 30 are electrically connected by means of conductive bumps 51 and 52.

The vacant portion 50 is required to maintain airtight. Therefore, the surface acoustic wave element 40 is covered with a hardening resin 60. The hardening resin 60 is brought into contact with the upper outer peripheral surface of the flat-plate substrate 30 to maintain the vacant portion 50 airtight.

A conventional device shown in FIG. 12 is an example employing a cover 70 in place of the hardening resin 60 mentioned above.

In such an electronic part (device), the airtightness of the vacant portion 50 varies depending upon the width (L1) of the joint portion 80 between the flat-plate substrate 30 and the resin 60 (or the cover 70). This is because the moisture goes into and comes out of the vacant portion 50 by diffusion from and to the outside primarily through the interface between the flat-plate substrate 30 and the resin 60 (or the cover 70) rather than through the flat-plate substrate 30 and through the resin 60 (or the cover 70). Therefore, to improve the airtightness of the vacant portion 50, it is conceivable to increase the joint length between the flat-plate substrate 30 and the resin 60.

On the other hand, it has been desired to miniaturize and lighten the electronic part (device) of this type. When the joint length is reduced, that is, the length of the interface of the joint portion is reduced, the airtightness deteriorates. To compensate for the airtightness, it may be conceivable to provide a protection layer to the functioning section 41 of the acoustic surface wave element. However, the protection layer, if provided, will degrade the properties of the element and increase the number of manufacturing steps, raising the cost.

### BRIEF SUMMARY OF THE INVENTION

In view of the circumstances, an object of the present invention is to provide a surface acoustic wave device manufactured at low cost and capable of further being reduced in size and attaining satisfactory airtightness of the vacant portion.

To attain the aforementioned object, the present invention provides a surface acoustic wave device comprising a surface acoustic wave element formed of a piezoelectric substrate having a functioning portion on one of the surfaces thereof; a flat-plate substrate having a surface arranged so as to face the surface on which the functioning portion of the surface acoustic wave element is formed, with a vacant portion interposed between the surfaces, and having a bonding pad which is connected to a bonding pad of the surface acoustic wave element, the flat-plate substrate having a long side of 3 mm or less; a stepped portion formed on an edge of the flat plate substrate and having a difference in height from the surface of the substrate; and a covering member integrally covering the surface of the stepped portion and the outer surface of the surface acoustic wave element and coinciding the stepped portion to ensure the airtightness of the vacant portion.

By virtue of these features, the size of the substrate can be reduced without reducing the length of the interface between the flat-plate substrate and the resin and without increasing the number of manufacturing steps. Hence, an electronic part can be miniaturized at low cost while maintaining sufficient airtightness.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1A is a sectional view showing a structure according to an embodiment of the present invention;

FIG. 1B is an enlarged sectional view, partially cut away from FIG. 1A;

FIG. 1C is a modified example of the partial structure shown in FIG. 1B;

FIG. 1D is another modified example of the partial structure shown in FIG. 1B;

FIG. 2 is a plan view of a surface acoustic wave device according to the present invention, as viewed from the back surface;

FIG. 3 is a sectional view of a bonding pad portion of a surface acoustic wave device according to the present invention;

FIG. 4 is a sectional view showing a structure according to another embodiment of the present invention;

FIG. 5 is a sectional view showing a structure according to another embodiment of the present invention;

FIG. 6 is a sectional view showing a structure according to another embodiment of the present invention;

FIG. 7 is a sectional view showing a structure according to another embodiment of the present invention;

FIG. 8 is a sectional view showing a structure according to another embodiment of the present invention;

FIG. 9 is a sectional view showing a structure according to another embodiment of the present invention;

FIG. 10A is a sectional view showing a structure according to another embodiment of the present invention;

FIG. 10B is a sectional view partly cut away from FIG. 10A;

FIG. 11 is a sectional view showing the structure of a conventional surface acoustic wave device; and

FIG. 12 is a sectional view showing the structure of a conventional surface acoustic wave device.

### DETAILED DESCRIPTION OF THE INVENTION

Now, embodiments of the present invention will be explained with reference to the accompanying drawings.

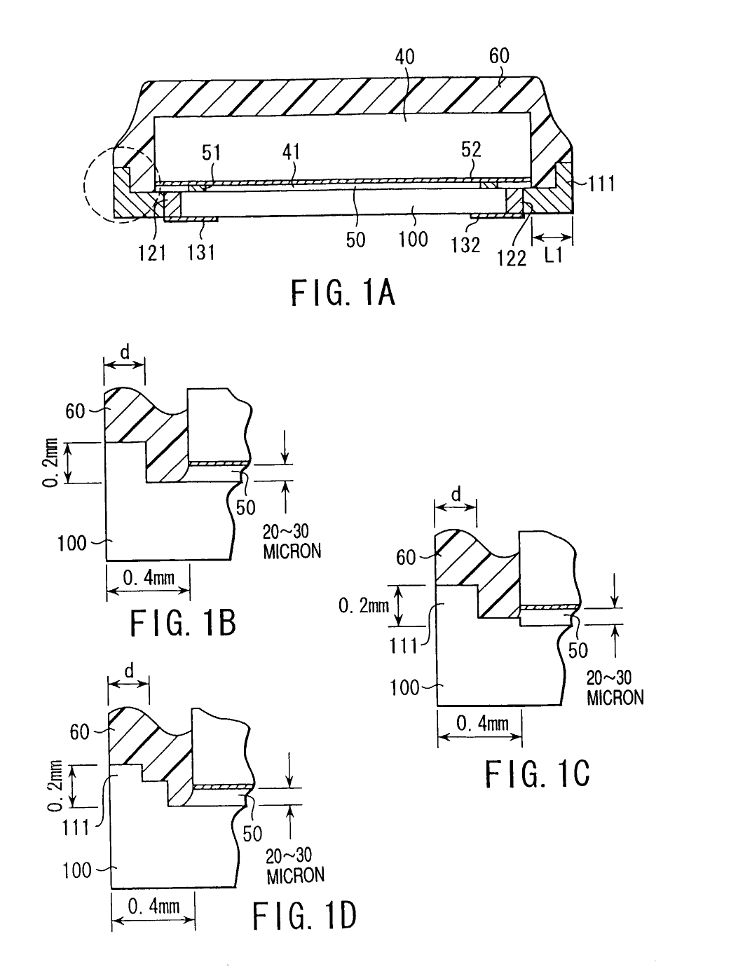

FIG. 1 is an embodiment of the present invention. Reference numeral 100 denotes a flat-plate substrate. On the upper surface of the flat-plate substrate 100, a wiring pattern is formed which is connected via a through-hole 101 to a lead pattern formed on the lower surface thereof. Above the upper surface of the flat-plate substrate 100, a surface acoustic wave element 40 is arranged in parallel to the upper surface. The surface acoustic wave element 40 has a functioning portion (Inter digital transducer portion) 41 formed on a piezoelectric substrate. The functioning portion 41 is arranged so as to face the upper surface of the flat-plate substrate 100. The connection is made by such an arrangement. Such a connection is called as a flip chip or facedown connection.

A vacant portion 50 is provided between the opposed surfaces of the surface acoustic wave element 40 and the flat-plate substrate 100. This is because the opposed surfaces of the flat-plate substrate 100 and the surface acoustic wave element 40 cannot be brought in contact with each other since the surface acoustic wave element 40 has a functional property of transmitting a surface acoustic wave.

The bonding pads on the opposed surfaces of the surface acoustic wave element 40 and the flat-plate substrate 100 are electrically connected by means of conductive bumps 51 and 52. As the material of the bumps 51 and 52, cold or silver is used. Electrodes are connected through the bumps by transmitting an ultrasonic wave to the side of the surface acoustic wave element.

The bumps 51 and 52 are positioned between mutual bonding pads of the opposed surfaces of the acoustic wave element 40 and the flat-plate substrate 100. Wiring is printed on the flat-plate substrate 100. Further, the printed wiring is electrically led to the rear surface side of the flat-plate substrate 100 by way of through-hole contacts 121, 121. On the rear surface of the flat-plate substrate 100, terminal electrodes 131, 132 are formed of gold or aluminum by pattern printing. The through-hole contacts 121, 122 are connected to the terminal electrodes 131 and 132, respectively, through which an input signal is supplied, earth potential is given to the functioning portion of the surface acoustic wave element 40, and through which an output signal is taken out from the functioning portion.

The through-hole contacts 121 and 122 are arranged at least inside a stepped portion (projecting potion) 111 described later, thereby contributing to miniaturization of the surface acoustic wave device.

The vacant portion 50 mentioned above must be maintained airtight. The surface acoustic wave element 40 is covered with a hardening resin 60. The hardening resin 60 and the outer peripheral upper surface of the flat-plate substrate 100 are connected to each other, thereby ensuring the airtightness of the vacant portion 50.

In the present invention, in the outer periphery of the flat-plate substrate 100, the stepped portion (projecting portion) 111 is formed, which projects upward leading to a higher portion. Since the stepped portion 111 is provided around the flat-plate substrate, the length of the interface between the hardening resin 60 and the flat-plate substrate 100 can be increased in the acoustic wave surface device of the present invention.

More specifically, if the length of the contact interface is 0.4 mm or less, moisture is likely to enter. However, in this embodiment, as shown in FIGS. 1B to 1D, even if the minimum wall thickness of the end surface of the hardening resin 60 (or the distance between the surface acoustic wave element 40 and the end surface of the substrate 100) is 0.4 mm, the length of the hardening resin 60 in contact with the substrate can be increased by 0.2 mm due to the presence of a stepped portion (the height of the step: e.g., 0.2 mm) at the edge of the flat-plate substrate 100. Because of the structural feature, it is possible to increase the effect of preventing moisture from going into the vacant portion 50 from the outside. In other words, the airtightness of the vacant portion can be improved.

If the airtightness of the vacant portion 50 is insufficient and thus moisture enters from the outside, an aluminum film used as the electrode of the surface acoustic wave element 40 reacts with a gold bump of the electrode portion to give rise to corrosion, leading to deterioration of durability and performance of the device. As described in the above, since the airtightness of the vacant portion 50 can be satisfactorily maintained in the device of the present invention, it is possible to prevent the deterioration of durability and performance of the device.

Now, the frequency band employed by the surface acoustic wave device according to the present invention and the size of individual portions of the device will be explained.

The surface acoustic wave device of the present invention is applied to a portion into which a signal within a radio-frequency (RF) band of 800 MHz or more in terms of a middle frequency is input. The surface acoustic wave device of the present invention has a size of 3×3 mm or less, about 2.5 mm×2.0 mm or 2.0×1.5 mm in a plan view. The size of the portion having the stepped portion 111 formed therein and in contact with the hardening resin 60 is about 0.4 mm. The thickness d of the stepped portion 111 is <0.4 mm.

Because of these features, the airtightness of the device can be markedly improved compared to a conventional device. In this case, provided that at least the same reliability as that of a conventional device is ensured with respect to airtightness, it is possible to reduce the outer dimensions of the flat-plate substrate 100 from those of a conventional substrate.

The surface acoustic wave device thus constructed was subjected to a reliability test performed in high temperature and humidity environment. As a result, at least the same reliability as that of a conventional device can be ensured with respect to reliability. The length L2 (0.4 mm) of the portion of the aforementioned device in which the interface of the flat-plate substrate 30 is present can be further reduced to 0.3 mm.

Accordingly, when the lengths of the right and left portions are added, the size of the device can be reduced by 0.2 mm, compared to the aforementioned device.

By virtue of the structure, the fixation effect of the hardening resin 60 (cover 200) to the flat-plate substrate 100 is improved, and especially, the fixation strength against lateral vibration (i.e., in parallel with the flat surface) can be improved.

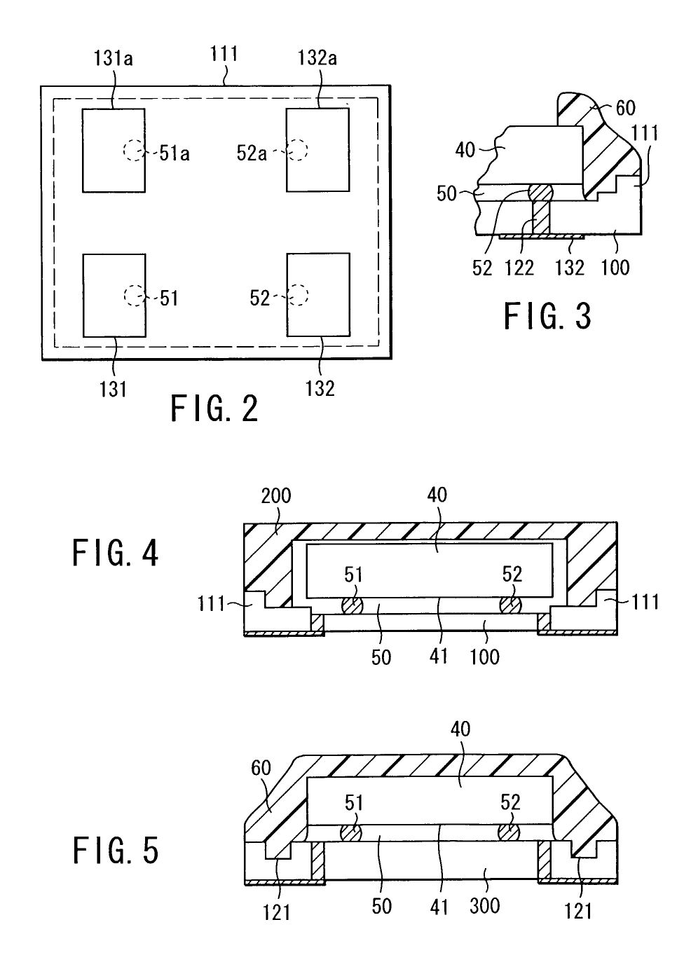

FIG. 2 is a plan view of the surface acoustic wave device of the present invention as viewed from the rear surface. The terminal electrodes 131 and 131a are used as a signal input terminal and a grounding terminal at the input side. Similarly, the terminal electrode 132 and 132a are used as a signal output terminal and a grounding terminal at the output side. This embodiment shows the device having four terminal electrodes. However, the device of the present invention is not limited to this.

FIG. 3 shows another example of the arrangement of a bump 52, through-hole contact 122, and terminal electrode 132. Although this figure shows only the portion around the bump 52, the structural arrangement around another bump is similar to this. In this embodiment, the bump 52 and the through-hole contact 122 are positioned to face each other. With this arrangement, the run length of wiring printed on a flat-plate substrate 100 can be reduced.

FIG. 4 shows another embodiment of the present invention. The present invention is not limited to the aforementioned embodiment. As the member covering the surface acoustic wave element 40, a cover 200 may be used in place of the hardening resin 60. In this case, the contact portion between the cover 200 and the flat-plate substrate 100 has a shape coinciding with that of the stepped portion 111 previously mentioned. The contact portion between the cover 200 and the flat-plate substrate 100 may be adhered with an adhesive agent. The same explanation as mentioned with reference to FIGS. 1B-1D and FIGS. 2 and 3 may also fit in this embodiment.

FIG. 5 shows another embodiment of the invention. In this embodiment, a groove portion 121 (stepped portion) is formed around the entire periphery of the upper surface of a flat-plate substrate 300. Therefore, the hardening resin 60 enters the groove portion 121 to execute fixation.

With this structure, since the groove 121 absorbs the hardening resin 60, the hardening resin 60 can be prevented from going into the vacant portion 50 to cause a problem.

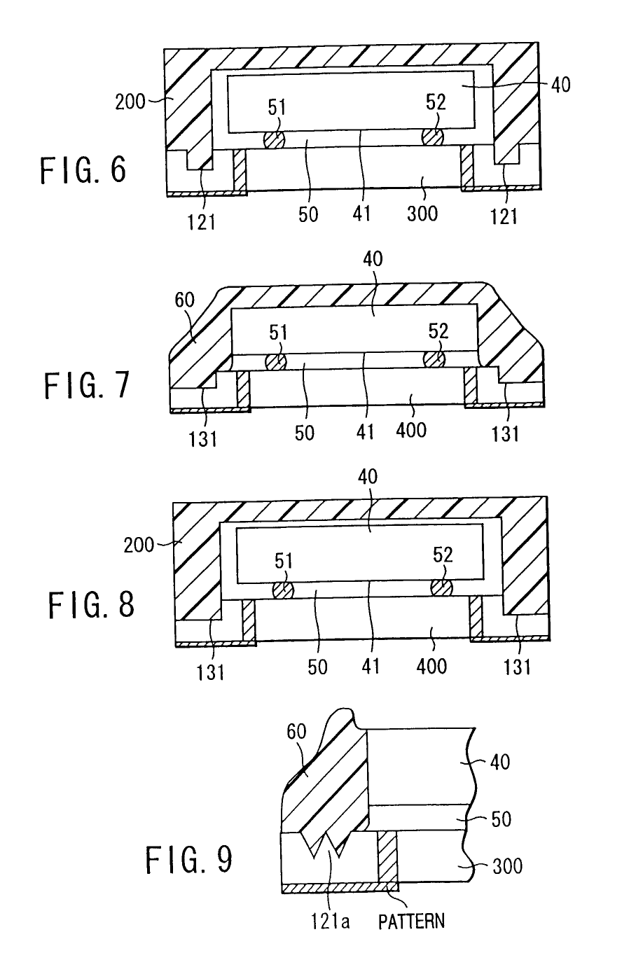

FIG. 6 is an example employing a flat-plate substrate 300 shown in FIG. 5 and a cover 200 serving as a covering member. In this case, the shape of the edge portion of the substrate is designed such that the surfaces of the cover 200 and the flat-plate substrate 300 in contact with each other mutually coincide.

The same effects as those explained in FIGS. 1-3 can be obtained in embodiments of FIGS. 4-6.

FIG. 7 shows another embodiment of the invention. In this embodiment, the edge portion around the upper surface of a flat-plate substrate 400 is appropriately reduced in thickness (having a L-letter sectional shape) up to an appropriate thickness to form a stepped portion 131. Therefore, the surface acoustic wave element 40 is covered with a hardening resin 60. In the state where the hardening resin 60 is in contact with the substrate, the hardening resin 60 is joined such that it is engaged with the stepped portion 131.

FIG. 8 is an example of a device employing the same flat-plate substrate 400 shown in FIG. 7 and a cover 200 as the covering member. In this case, the shape of the edge portion of the substrate is designed such that the surfaces of the cover 200 and the flat-plate substrate 400 in contact with each other mutually coincide.

The same effects as explained with reference to FIGS. 1 to 3 can be obtained in embodiments of FIGS. 7 and 8.

FIG. 9 is another embodiment of the present invention. The shape of the stepped portion is not limited to those shown in the aforementioned embodiments and various shapes may be employed. The embodiment of FIG. 9 provides an example of a stepped portion 121a having a plurality of grooves arranged in parallel. Like reference numerals designate like structural elements throughout the drawings.

In the present invention, the stepped portion to be provided to the flat-plate substrate may have a plurality of steps. The outer side of the stepped portion may be higher or lower than the inside. Alternatively, part of the stepped portion may be depressed or project. The flat-plate substrate is not limited to materials such as ceramic and plastic. A substrate formed of an inexpensive resin may be used.

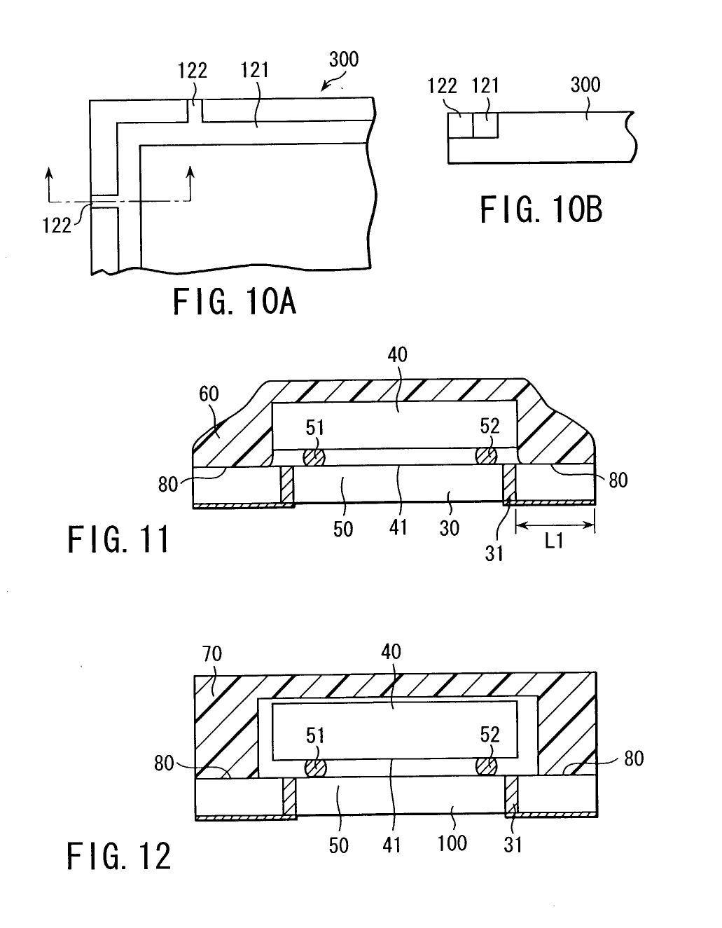

FIGS. 10A and 10B show an embodiment whose structure is the same as that shown in FIG. 1 or FIG. 3 except that a groove 121 has plurality of cut-away portions 122. By virtue of this structure, even if the hardening resin 60 enters the groove 121 and comes to overflow from the groove 121, it is released from the cut-away portion 122. In this manner, the hardening resin is prevented from going into the vacant portion 50. When the amount of hardening resin 60 is determined in the manufacturing step, the amount of the hardening resin may be set roughly. As a result, manufacturing can be made easily. The technical idea can be applied to the flat-plate substrate 300 shown in FIG. 1. In place of the cut-away portion 122 for absorbing the overflow, a pot may be provided to the side of a groove.

As explained above, the present invention makes it possible to reduce the cost and size while good airtightness of the vacant portion is maintained. More specifically, the size of the substrate can be reduced without reducing the length of the interface between the substrate and the resin and without increasing the number of manufacturing steps. As a result, it is possible to miniaturize electronic parts while maintaining sufficient airtightness at low cost.

The present invention is used as a part of resonators, resonator-form filters, and oscillators. The part according to the present invention is effectively used as a surface acoustic wave device (SAW filter). The surface acoustic wave device is suitable for use in electronic devices including mobile communication machines such as cellular phones.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A surface acoustic wave device comprising
a surface acoustic wave element formed of a piezoelectric substrate having a functioning portion on one of the surfaces thereof;
a flat-plate substrate having a surface arranged so as to face the surface on which functioning portion of said surface acoustic wave element is formed, with a vacant portion interposed between the surfaces, and having a bonding pad which is connected to a bonding pad of said surface acoustic wave element, said flat-plate substrate having a long side of 3 mm or less;
a stepped portion formed on an edge of said flat plate substrate and having a difference in height from the surface of the substrate; and
a covering member integrally covering the surface of the stepped portion and the outer surface of the surface acoustic wave element and coinciding the stepped portion to ensure the airtightness of the vacant portion.

2. A surface acoustic wave device according to claim 1, wherein a plan-view shape of said flat-plate substrate is a rectangle having a long side of about 2.5 mm or less.

3. A surface acoustic wave device according to claim 2, wherein a signal to be supplied to the surface acoustic wave element falls within a frequency range of 800 MHz or more.

4. A surface acoustic wave device according to claim 1, wherein said covering member is a hardening resin.

5. A surface acoustic wave device according to claim 1, wherein said stepped portion has a projection provided around the periphery of the edge of said flat-plate substrate so as to stand from the substrate.

6. A surface acoustic wave device according to claim 1, wherein said stepped portion is a groove formed around the edge portion of the flat-plate substrate and in the upper peripheral surface.

7. A surface acoustic wave device according to claim 1, wherein said stepped portion has a step formed by reducing the thickness of the outer-side edge portion of the flat-plate substrate.

8. A surface acoustic wave device according to claim 6, wherein said stepped portion partially has a cut-away portion.
